(19) United States
(12) Patent Application Publication
(10) Pub. No.: US 2026/0050380 A1
(43) Pub. Date: Feb. 19, 2026

(54) STORAGE DEVICE

(71) Applicant: Samsung Electronics Co., Ltd., Suwon-si, Gyeonggi-do (KR)

(72) Inventor: Jiwoon PARK, Suwon-si (KR)

(73) Assignee: Samsung Electronics Co., Ltd., Suwon-si, Gyeonggi-do (KR)

(21) Appl. No.: 19/214,781

(22) Filed: May 21, 2025

(30) Foreign Application Priority Data
Aug. 19, 2024 (KR) 10-2024-0110827

(51) Int. Cl. G06F 3/06

(52) U.S. Cl. CPC G06F 3/0611; G06F 3/0659; G06F 3/0679

(57) ABSTRACT

Disclosed is a storage device including a first package including first dies, a second package including second dies, a first chip enable (CE) signal line connected in common to the first and second packages, a first command signal line connected in common to the first and second packages, and a controller configured to select one die of dies included in packages connected in common to the first CE signal line by applying a CE signal to the first CE signal line and a chip enable reduction (CER) command signal to the first command signal line. The CER command signal includes at least one package identification bit for package selection and at least one die identification bit for die selection, and each of the first and second packages includes at least one identification pin applied with at least one package identification voltage respectively corresponding to at least one package identification bit.

### CROSS-REFERENCE TO RELATED APPLICATIONS

This application claims priority under 35 U.S.C. § 119 to Korean Patent Application No. 10-2024-0110827 filed on Aug. 19, 2024, in the Korean Intellectual Property Office, the disclosures of which are incorporated by reference herein in their entireties.

### BACKGROUND

Example Embodiments of the present disclosure described herein relate to a storage device.

A semiconductor memory device may be classified as a volatile memory or a non-volatile memory. Volatile memory may be faster in read and write speeds but loses data stored therein when a power is turned off. Because non-volatile memory retains data stored therein even when a power is turned off, non-volatile memory may be used in a storage device which may need to maintain the stored data regardless of a power state.

In the case of a storage device such as a solid state drive (SSD), there is continuously increasing demand for higher-capacity products. More memory packages may be mounted in the storage device to increase the capacity of the storage device, which may increase in the number of chip enable (CE) pins on a controller and the number of CE signal lines between the controller and the memory package. Accordingly, the size of the controller and the number of CE signal lines may increase, and/or the manufacturing costs of the storage device increase.

### SUMMARY

Some example embodiments of the present disclosure provide a storage device in which the number of CE pins of a controller and the number of CE signal lines are decreased.

According to some example embodiments, a storage device may include a first package including first dies, a second package including second dies, a first chip enable (CE) signal line connected in common to the first and second packages, a first command signal line connected in common to the first and second packages, and a controller configured to select one die of dies included in packages connected in common to the first CE signal line by applying a CE signal to the first CE signal line and a chip enable reduction (CER) command signal to the first command signal line. The CER command signal includes at least one package identification bit for package selection and at least one die identification bit for die selection, and each of the first and second packages includes at least one identification pin applied with at least one package identification voltage respectively corresponding to the at least one package identification bit.

According to some example embodiments, a storage device may include a plurality of NAND packages, a controller configured to control the plurality of NAND packages through a plurality of channels, and a plurality of chip enable (CE) signal lines configured to transfer a plurality of CE signals respectively corresponding to the plurality of channels of the plurality of NAND packages. The plurality of NAND packages include a first NAND package including a plurality of first dies and a first CE pin connected in common to at least one of the plurality of first dies, and a second NAND package including a plurality of second dies and a second CE pin connected in common to at least one of the plurality of second dies. The controller includes a third CE pin configured to output a first CE signal corresponding to a first channel among the plurality of channels, the plurality of CE signal lines include a first CE signal line including a first end connected to the third CE pin, and a second end connected in common to the first CE pin and the second CE pin. Each of the first and second NAND packages includes an identification pin applied with a package identification voltage for distinguishing the first NAND package and the second NAND package.

According to some example embodiments, a storage device may include a first package including a first chip enable (CE) pin, first dies connected in common to the first CE pin, a second CE pin, and second dies connected in common to the second CE pin, a second package including a third CE pin, third dies connected in common to the third CE pin, a fourth CE pin, and fourth dies connected in common to the fourth CE pin, a controller including a fifth CE pin configured to output a first CE signal corresponding to a first channel, and a sixth CE pin configured to output a second CE signal corresponding to a second channel, a first CE signal line including a first end connected to the fifth CE pin, and a second end connected in common to the first CE pin and the third CE pin, and a second CE signal line including a first end connected to the sixth CE pin, and a second end connected in common to the second CE pin and the fourth CE pin. Each of the first and second packages includes an identification pin applied with an identification voltage for distinguishing the first and second packages.

### BRIEF DESCRIPTION OF THE FIGURES

The above and other objects and features of the present disclosure will become apparent by describing in detail some example embodiments thereof with reference to the accompanying drawings.

FIG. 1 is a block diagram of a storage device according to some example embodiments of the present disclosure.

FIG. 2 is a block diagram of a storage device according to some example embodiments of the present disclosure.

FIG. 3 is a block diagram of a storage device according to some example embodiments of the present disclosure.

FIG. 4 is a block diagram of a conventional storage device.

FIG. 5 is a block diagram of a storage device according to some example embodiments of the present disclosure.

FIG. 6 is a block diagram of a storage device according to some example embodiments of the present disclosure.

FIG. 7 is a block diagram of a storage device according to some example embodiments of the present disclosure.

FIG. 8 is a block diagram of a storage device according to some example embodiments of the present disclosure.

FIG. 9 is a diagram illustrating some example embodiments associated with die address allocation.

FIG. 10 is a diagram illustrating some example embodiments associated with die address allocation.

FIG. 11 is a diagram illustrating some example embodiments associated with die address allocation.

FIG. 12 is a block diagram of a storage device according to some example embodiments of the present disclosure.

FIG. 13 is a block diagram of a storage device according to some example embodiments of the present disclosure.

### DETAILED DESCRIPTION

In the present disclosure, the expressions “first”, “second”, etc. may modify various components regardless of the order and/or the importance, are only used to distinguish one component from another component, and are not intended to limit the order or importance of components.

Additionally, when it is mentioned in the present disclosure that one component (e.g., a first component) is “coupled with/to or connected to” another component (e.g., a second component), it may be understood that this includes not only the case where the first component is directly connected to the second component but also the case where the first component is connected to the second component through another component (e.g., a third component).

Hereinafter, various embodiments of the present disclosure will be described in detail with reference to the accompanying drawings to such an extent that one skilled in the art to which the present disclosure belongs may easily carry the present disclosure.

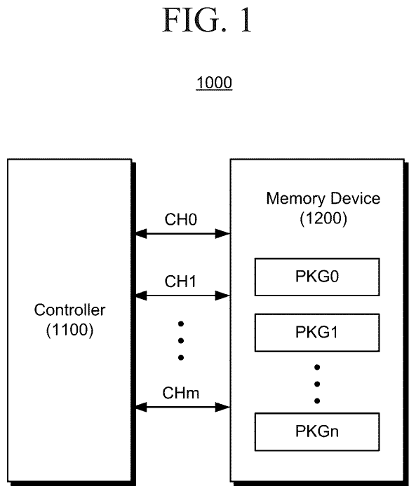

FIG. 1 is a block diagram of a storage device according to some example embodiments of the present disclosure. Referring to FIG. 1, a storage device 1000 may include a controller 1100 and a memory device 1200.

The memory device 1200 may include a plurality of packages PKG0, PKG1, . . . , PKGn. In some example embodiments, each of the plurality of packages PKG0, PKG1, . . . , PKGn may be a semiconductor memory package including a plurality of dies. For example, each of the plurality of packages PKG0, PKG1, . . . , PKGn may be a multi-chip package such as a dual die package (DDP), a quadruple die package (QDP), an octuple die package (ODP), a hexadecimal die package (HDP), or a 32 die package (32DP). In some example embodiments, the number of dies included in the multi-chip package is not limited thereto.

The plurality of dies included in each of the packages PKG0, PKG1, . . . , PKGn may be non-volatile memory chips. For example, the plurality of dies may be NAND flash memory chips. According to some example embodiments, at least one of the plurality of dies may be a vertical NAND (VNAND) flash memory chip. The vertical NAND flash memory chip may include word lines stacked on a substrate in a vertical direction and cell strings each including a plurality of memory cells respectively connected to the word lines. However, some example embodiments is not limited thereto. For example, the plurality of dies included in each of the packages PKG0, PKG1, . . . , PKGn may be NOR flash memory chips.

According to some example embodiments, the plurality of dies included in each of the packages PKG0, PKG1, . . . , PKGn may include various kinds of memory chips. For example, the plurality of dies may include a dynamic random access memory (DRAM) chip such as a double data rate synchronous dynamic random access memory (DDR SDRAM), a low power double data rate (LPDDR) SDRAM, a graphics double data rate (GDDR) SDRAM, or a Rambus DRAM (RDRAM). Also, the plurality of dies may include a resistive memory chip such as a resistive RAM (ReRAM), a phase change RAM (PRAM), or a magnetic RAM (MRAM).

Through a plurality of channels CH0, CH1, . . . , CHm, the memory device 1200 may receive a command and an address from the controller 1100 and may transmit/receive data to/from the controller 1100. The memory device 1200 may receive data to be stored in the memory device 1200 from the controller 1100 or may transmit data read from the memory device 1200 to the controller 1100. The interface between the memory device 1200 and the controller 1100 may be implemented to comply with the standard protocol such as toggle or ONFI.

The controller 1100 may control the plurality of packages PKG0, PKG1, . . . , PKGn included in the memory device 1200 through the plurality of channels CH0, CH1, . . . , CHm. According to some example embodiments, the controller 1100 may control the plurality of packages PKG0, PKG1, . . . , PKGn by using one chip enable (CE) signal for each channel. In this case, one CE signal may take charge of at least two packages.

To this end, an address may be allocated to each of the dies included in the plurality of packages PKG0, PKG1, . . . , PKGn. In some example embodiments, the address may include a package identification bit for identifying a package where the corresponding die is included, and a die identification bit for identifying the corresponding die among the dies in the package. The address allocated to each die may correspond to a package identification voltage and a die identification voltage respectively applied to a package identification pad and a die identification pad, which will be described later.

For example, the controller 1100 may transmit the CE signal and a chip enable reduction (CER) command signal to the memory device 1200 to select one of dies included in at least two packages which the transmitted CE signal is responsible for. In some example embodiments, the CER command may include a package identification bit and a die identification bit allocated to a die to be selected. The selected die may operate depending on an individual command from the controller 1100.

In the case of a conventional technology, a plurality of packages are capable of being controlled through one channel, and one CE signal also takes charge of one package. Accordingly, CE signals may be required as much as the number of packages to control a plurality of packages.

However, according to some example embodiments of the present disclosure, as described above, a plurality of packages may be controlled by using one CE signal. Accordingly, there may be provided a storage device in which the number of CE pins of a controller and the number of CE signal lines are decreased. This may mean that the size of a storage device and manufacturing costs are reduced.

In some example embodiments, the storage device 1000 may be an internal memory embedded in an electronic device. For example, the storage device 1000 may be a solid state drive (SSD), an embedded universal flash storage (UFS) or an embedded multi-media card (eMMC). In some example embodiments, the storage device 1000 may be an external memory which is removable from the electronic device. For example, the storage device 1000 may include a UFS memory card, a compact flash (CF) card, a secure digital (SD) card, a micro-SD card, a mini-SD card, an extreme digital (xD) card, or a memory stick.

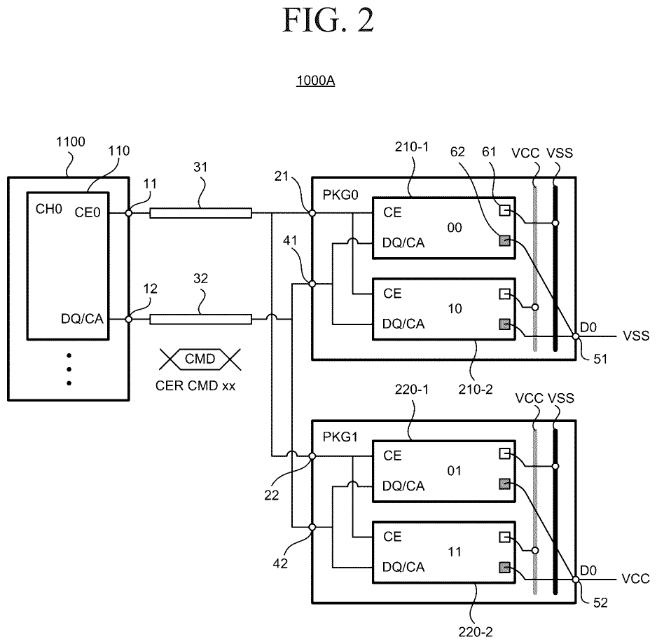

FIG. 2 is a block diagram of a storage device according to some example embodiments of the present disclosure. A storage device 1000A of FIG. 2 may be an implementation example embodiment of the storage device 1000 of FIG. 1, but example embodiments are not limited thereto.

FIG. 2 shows some example embodiments in which the controller 1100 controls two 1CE dual die package (DDP). Referring to FIG. 2, the storage device 1000A may include the controller 1100, a first package PKG0, a second package PKG1, a first CE signal line 31, and a first command signal line 32.

The first package PKG0 may include first dies 210-1 and 210-2. Also, the first package PKG0 may include a first CE pin 21 to which a CE pad CE of the first die 210-1 and a CE pad CE of the first die 210-2 are connected in common. Each of the first dies 210-1 and 210-2 may receive the CE signal through the CE pad CE. The first package PKG0 includes two dies 210-1 and 210-2 and one CE pin 21, the first package PKG0 may be the ICE DDP.

Meanwhile, the first package PKG0 may include a first command pin 41 to which a command pad DQ/CA of the first die 210-1 and a command pad DQ/CA of the first die 210-2 are connected in common. Each of the first dies 210-1 and 210-2 may receive a command signal through the command pad DQ/CA. Because the command signal includes a plurality of bits, unlike the CE pad CE, the command pad DQ/CA may actually include a plurality of pads for receiving the plurality of bits included in the command signal, respectively.

Meanwhile, the command pad DQ/CA may be a DQ pad or a CA pad depending on a kind of the standard protocol. For example, in the case of toggle 5.1, because each die receives a command through a DQ pad and does not include a separate CA pad, the command pad DQ/CA may be the DQ pad. Meanwhile the case of toggle 6.0, because each die includes a separate CA pad for receiving a command signal, the command pad DQ/CA may be the CA pad. Below, a command pad is marked by “DQ/CA” to include all the two cases.

The second package PKG1 may be similar in configuration to the first package PKG0. In detail, the second package PKG1 may include second dies 220-1 and 220-2. Also, the second package PKG1 may include a second CE pin 22 to which a CE pad CE of the second die 220-1 and a CE pad CE of the second die 220-2 are connected in common. Each of the second dies 220-1 and 220-2 may receive the CE signal through the CE pad CE.

Meanwhile, the second package PKG1 may include a second command pin 42 to which a command pad DQ/CA of the second die 220-1 and a command pad DQ/CA of the second die 220-2 are connected in common. Each of the second dies 220-1 and 220-2 may receive a command signal through the command pad DQ/CA.

In this case, according to some example embodiments of the present disclosure, an address may be allocated to each of the dies 210-1, 210-2, 220-1, and 220-2 included in the first and second packages PKG0 and PKG1. In this case, the address may include a package identification bit for distinguishing packages and a die identification bit for distinguishing dies.

FIG. 2 shows the case where addresses are formed in order of the die identification bit and the package identification bit, and Table 1 below shows addresses respectively allocated to the dies 210-1, 210-2, 220-1, and 220-2.

TABLE 1

| | Die identification | Package identification |
|---|---|---|
| | bit | bit |
| PKG0 first die (210-1) | 0 | 0 |
| PKG0 first die (210-2) | 1 | 0 |
| PKG1 second die (220-1) | 0 | 1 |
| PKG1 second die (220-2) | 1 | 1 |

Referring to Table 1 above, it may be understood that the dies 210-1, 210-2, 220-1, and 220-2 included in the packages PKG0 and PKG1 connected in common to the first CE signal line 31 are distinguished from each other through the allocated addresses.

According to some example embodiments, each of the dies 210-1, 210-2, 220-1, and 220-2 may include a die identification pad 61 and a package identification pad 62. A die identification voltage corresponding to a bit value of a die identification bit may be applied to the die identification pad 61, and a package identification voltage corresponding to a bit value of a package identification bit may be applied to the package identification pad 62. Accordingly, the address allocation may be implemented. In some example embodiments, voltages of different levels may be used as sources of the die identification voltage and the package identification voltage. For example, a power supply voltage VCC and a ground voltage VSS may be used to indicate different bit values (e.g., “1” and “0”), but example embodiments are not limited thereto.

Meanwhile, according to some example embodiments, the die identification voltage may be directly applied to the die identification pad 61 of a die included in the corresponding package from voltage sources of two different levels, which are provided inside each of the packages PKG0 and PKG1. In this case, the voltage sources may be a power supply voltage line and a ground voltage line provided in each of the packages PKG0 and PKG1, but example embodiments are not limited thereto.

In contrast, in the case of the package identification voltage, voltages of two different levels, which are provided outside each of the packages PKG0 and PKG1, may be used as sources. For example, a power supply voltage line and a ground voltage line provided in a circuit board of the storage device 1000A may be used as the sources of the package identification voltage, but the example embodiments are not limited thereto. According to some example embodiments, the first package PKG0 may include an identification pin 51, and the second package PKG1 may include an identification pin 52. In this case, the package identification voltage may be applied to the corresponding package identification pad 62 from the source through the identification pin 51 or 52.

The controller 1100 may include a first control circuit 110 which generates a CE signal CE0 corresponding to the first channel CH0 and a command signal DQ/CA. The CE signal CE0 and the command signal DQ/CA generated by the first control circuit 110 may be respectively output to a first CE pin 11 and a first command pin 12 of the controller 1100.

A first end of the first CE signal line 31 may be connected to the first CE pin 11 of the controller 1100, and a second end of the first CE signal line 31 may be connected to the first CE pin 21 of the first package PKG0 and the second CE pin 22 of the second package PKG1.

A first end of the first command signal line 32 may be connected to the first command pin 12 of the controller 1100, and a second end of the first command signal line 32 may be connected to the first command pin 41 of the first package PKG0 and the second command pin 42 of the second package PKG1. In this case, the first command signal line 32 may mean a signal line through which a command signal (e.g., CER CMD) is transferred from the controller 1100 to the first and second packages PKG0 and PKG1. That is, according to some example embodiments, the first command signal line 32 may be implemented with a command/address signal line or may be implemented with a data signal line. For example, when a command signal is applied to packages through a data signal line depending on a kind of the standard protocol (e.g., in the case of toggle 5.1), the first command signal line 32 may be implemented with a data signal line. This is applied to the following description.

The first CE signal line 31 and the first command signal line 32 may be formed in the circuit board of the storage device 1000A, on which the controller 1100, the first package PKG0, and the second package PKG1 are mounted.

Meanwhile, to select one of the dies 210-1, 210-2, 220-1, and 220-2 included in the packages PKG0 and PKG1 connected in common to the first CE signal line 31, the controller 1100 may apply the CE signal CE0 to the first CE signal line 31 and may apply a CER command signal CER CMD to the first command signal line 32. In some example embodiments, the CER command signal CER CMD may include a die identification bit and a package identification bit allocated to a die to be selected.

In this case, the CE signal CE0 of the low level may be applied to all the dies 210-1, 210-2, 220-1, and 220-2 included in the first and second packages PKG0 and PKG1 connected in common to the first CE signal line 31, but one die corresponding to the die identification bit and the package identification bit included in the CER command signal CER CMD may be selected.

The one die thus selected may include a package identification pad to which a package identification voltage corresponding to a bit value of the package identification bit included in the CER command signal CER CMD is applied and a die identification pad to which a die identification voltage corresponding to a bit value of the die identification bit included in the CER command signal CER CMD is applied.

In FIG. 2, the case where each of the first and second packages PKG0 and PKG1 is the dual die package (DDP) including two dies is provided as an example, but example embodiments are not limited thereto. According to some example embodiments, each of the first and second packages PKG0 and PKG1 may be a quadruple die package (QDP) including 4 dies, an octuple die package (ODP) including 8 dies, a hexadecimal die package (HDP) including 16 dies, or a 32 die package (32DP) including 32 dies.

Also, only a configuration associated with the first channel CH0 is illustrated in FIG. 2, but example embodiments are not limited thereto. According to some example embodiments, it may be understood that the storage device 1000A further includes one or more additional channels. In this case, a configuration corresponding to each of additional channels may be the same as or similar to the configuration associated with the first channel CH0 illustrated in FIG. 2.

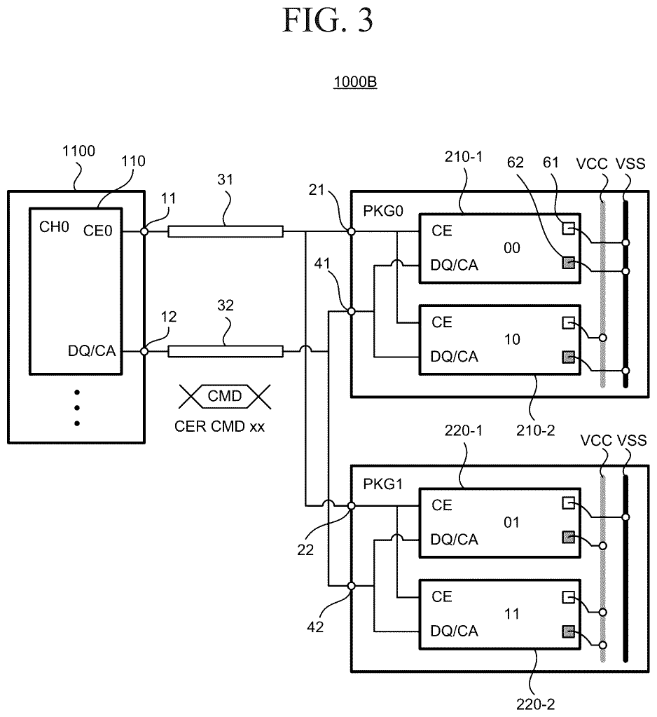

FIG. 3 is a block diagram of a storage device according to some example embodiments of the present disclosure. A storage device 1000B of FIG. 3 may be an implementation example embodiment of the storage device 1000 of FIG. 1, but example embodiments are not limited thereto.

Referring to FIG. 3, a configuration of the storage device 1000B is the same as the configuration of the storage device 1000A of FIG. 2 except that sources of the package identification voltage are different from each other. Accordingly, additional description will be omitted to avoid redundancy, and a difference will be mainly described.

According to some example embodiments of the present disclosure, the die identification voltage may be directly applied to the package identification pad 62 of a die included in the corresponding package from voltage sources of two different levels, which are provided inside each of the package PKG0 and PKG1. In this case, unlike the storage device 1000A of FIG. 2, the storage device 1000B may not require the identification pins 51 and 52. However, because the connection between the package identification pad 62 and the package identification voltage is made differently for each package, each of the first package PKG0 and the second package PKG1 should be manufactured through a separate manufacturing process.

In contrast, in the case of the storage device 1000A of FIG. 2, the first package PKG0 and the second package PKG1 may have the same structure in that the package identification pads 62 are connected to the corresponding identification pins 51 and 52. Accordingly, the first package PKG0 and the second package PKG1 may be manufactured through the same manufacturing process.

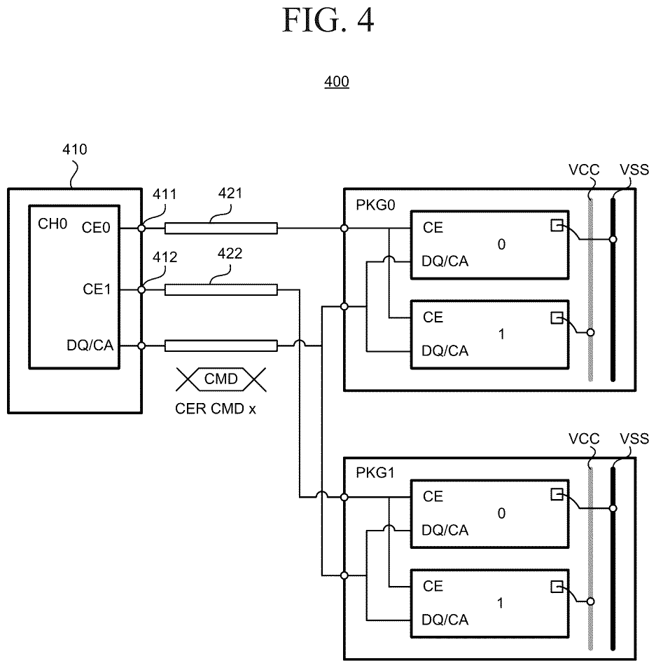

FIG. 4 is a block diagram of a conventional storage device. Referring to FIG. 4, a controller 410 of a storage device 400 may control two dual die packages PKG0 and PKG1 by using one channel CH0. In this case, the storage device 400 uses two CE signals CE0 and CE1 respectively corresponding to the packages PKG0 and PKG1.

To this end, the controller 410 may include two CE signal pins 411 and 412 through which the two CE signals CE0 and CE1 are respectively output. Also, the storage device 400 may include a first CE signal line 421 for transferring the first CE signal CE0 to the first package PKG0 and a second CE signal line 422 for transferring the second CE signal CE1 to the second package PKG1.

That is, in the case of a conventional technology, because a separate CE signal is used for each package, the CE pin of a controller and the CE signal line may be required as much as the number of packages targeted for control.

In contrast, according to some example embodiments of the present disclosure, because a plurality of packages are controlled by using one CE signal, the required number of CE signal lines and the required number of CE pins of the controller may be decreased.

In detail, in the case of some example embodiments in which two packages are controlled by using one channel, the number of CE signal lines and the number of CE pins of the controller may be decreased as much as 50% compared with the conventional technology. Also, in the case of some example embodiments in which four packages are controlled by using one channel, the number of CE signal lines and the number of CE pins of the controller may be decreased as much as 75% compared with the conventional technology. In addition, in the case of some example embodiments in which eight packages are controlled by using one channel, the number of CE signal lines and the number of CE pins of the controller may be decreased as much as 87.5% compared with the conventional technology.

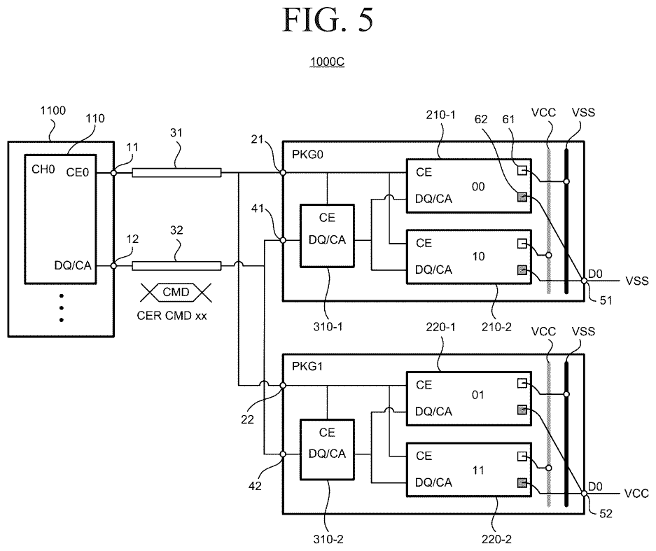

Meanwhile, as described above, according to some example embodiments of the present disclosure, because a plurality of packages are controlled through one channel, channel signals such as a CE signal and a CER command signal may weaken in the process of being transferred to a package through a CE signal line, a data (DQ) signal line, or a command/address (CA) signal line. To solve this issue, according to some example embodiments of the present disclosure, each package may include a buffer. Below, various embodiments in which a package includes a buffer will be described with reference to FIGS. 5 to 8.

FIG. 5 is a block diagram of a storage device according to some example embodiments of the present disclosure. A storage device 1000C of FIG. 5 may be an implementation example embodiment of the storage device 1000 of FIG. 1, but example embodiments are not limited thereto.

Referring to FIG. 5, a configuration of the storage device 1000C is the same as the configuration of the storage device 1000A of FIG. 2 except that the packages PKG0 and PKG1 include buffers 310-1 and 310-2, respectively. Accordingly, additional description will be omitted to avoid redundancy, and a difference will be mainly described.

According to some example embodiments, the first package PKG0 may include the first buffer 310-1. In this case, the first buffer 310-1 may receive the CE signal CE0 received through the first CE signal line 31 and the CER command signal CER CMD received through the first command signal line 32 and may transfer the CER command signal CER CMD to the first dies 210-1 and 210-2 based on the CE signal CE0.

Meanwhile, the second package PKG1 may include the second buffer 310-2. In this case, the second buffer 310-2 may receive the CE signal CE0 received through the first CE signal line 31 and the CER command signal CER CMD received through the first command signal line 32 and may transfer the CER command signal CER CMD to the second dies 220-1 and 220-2 based on the CE signal CE0.

In this case, the CER command signal CER CMD which weakens while passing through the first command signal line 32 may be recovered through the first and second buffers 310-1 and 310-2 and may be respectively transferred to the first and second dies 210-1, 210-2, 220-1, and 220-2.

The process in which one of the first and second dies 210-1, 210-2, 220-1, and 220-2 is selected based on the CE signal CE0 and the CER command signal CER CMD is the same as that described with reference to FIG. 2.

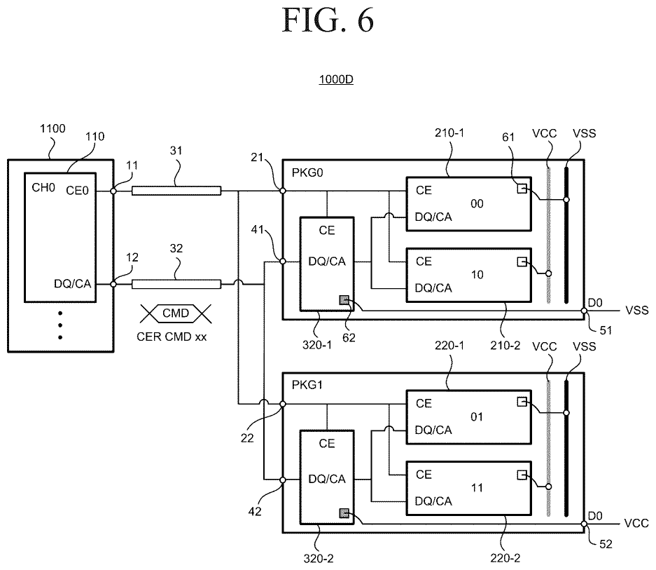

FIG. 6 is a block diagram of a storage device according to some example embodiments of the present disclosure. A storage device 1000D of FIG. 6 may be an implementation example embodiment of the storage device 1000 of FIG. 1, but example embodiments are not limited thereto.

Referring to FIG. 6, the storage device 1000D is the same as the storage device 1000C of FIG. 5 except for the package identification pads 62 are respectively placed in the buffers 320-1 and 320-2, not the dies 210-1, 210-2, 220-1, and 220-2. Accordingly, additional description will be omitted to avoid redundancy, and a difference will be mainly described.

According to some example embodiments, the first package PKG0 may include a first buffer 320-1. The first buffer 320-1 may include the package identification pad 62 connected to the identification pin 51 of the first package PKG0. Meanwhile, the second package PKG1 may include a second buffer 320-2. In this case, the second buffer 320-2 may include the package identification pad 62 connected to the identification pin 52 of the second package PKG1.

In this case, whether each of the first and second buffers 320-1 and 320-2 operates may be determined based on a received CER command signal and a package identification voltage applied to the corresponding package identification pad 62.

In detail, the CER command signal CER CMD include a package identification bit. Also, a package identification voltage corresponding to a bit value of a package identification bit allocated to a corresponding package is applied to each of the identification pins 51 and 52 of the packages PKG0 and PKG1. Accordingly, each of the first and second buffers 320-1 and 320-2 may compare a bit value of a package identification bit corresponding to a package identification voltage applied to the package identification pad 62 included in the corresponding buffer and a bit value of a package identification bit included in the CER command signal CER CMD. When a comparison result indicates that the bit values are matched, the corresponding buffer operates; when a comparison result indicates that the bit values are not matched, the corresponding buffer does not operate.

For example, when the bit value of the package identification bit included in the CER command signal CER CMD is “0”, because the bit value is matched with the bit value (e.g., “0”) corresponding to the package identification voltage VSS applied to the package identification pad 62 of the first buffer 320-1, the first buffer 320-1 may operate. Accordingly, the CER command signal CER CMD may be transferred to the first dies 210-1 and 210-2. In this case, because the second buffer 320-2 does not operate, the CER command signal CER CMD is not transferred to the second dies 220-1 and 220-2.

Meanwhile, the CER command signal CER CMD may include a die identification bit; because each of the first dies 210-1 and 210-2 includes the die identification pad 61 to which a die identification voltage corresponding to the allocated die identification bit is applied, one of the first dies 210-1 and 210-2 may be selected. In this case, the selected die may include the die identification pad 61 to which the die identification voltage corresponding to the bit value of the die identification bit included in the CER command signal CER CMD is applied.

When the bit value of the die identification bit included in the CER command signal CER CMD is “1”, the second buffer 320-2 may operate, and thus, the CER command signal CER CMD may be transferred to the second dies 220-1 and 220-2. Accordingly, one of the second dies 220-1 and 220-2 may be selected.

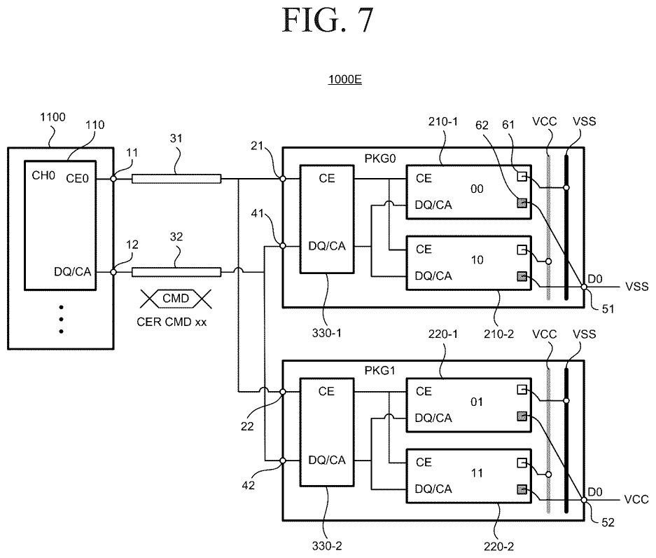

FIG. 7 is a block diagram of a storage device according to some example embodiments of the present disclosure. A storage device 1000E of FIG. 7 may be an implementation example embodiment of the storage device 1000 of FIG. 1, but example embodiments are not limited thereto.

Referring to FIG. 7, a configuration of the storage device 1000E is the same as the configuration of the storage device 1000A of FIG. 2 except that the packages PKG0 and PKG1 include buffers 330-1 and 330-2, respectively. Accordingly, additional description will be omitted to avoid redundancy, and a difference will be mainly described.

According to some example embodiments, the first package PKG0 may include the first buffer 330-1. In this case, the first buffer 330-1 may receive the CE signal CE0 received through the first CE signal line 31 and the CER command signal CER CMD received through the first command signal line 32 and may transfer the received CE signal CE0 and the received CER command signal CER CMD to the first dies 210-1 and 210-2.

Meanwhile, the second package PKG1 may include a second buffer 330-2. In this case, the second buffer 330-2 may receive the CE signal CE0 received through the first CE signal line 31 and the CER command signal CER CMD received through the first command signal line 32 and may transfer the received CE signal CE0 and the received CER command signal CER CMD to the second dies 220-1 and 220-2.

In this case, the CE signal CE0 and the CER command signal CER CMD which weaken while passing through the first command signal line 32 may be recovered through the first and second buffers 330-1 and 330-2 and may be respectively transferred to the first and second dies 210-1, 210-2, 220-1, and 220-2.

The process in which one of the first and second dies 210-1, 210-2, 220-1, and 220-2 is selected based on the CE signal CE0 and the CER command signal CER CMD is the same as that described with reference to FIG. 2.

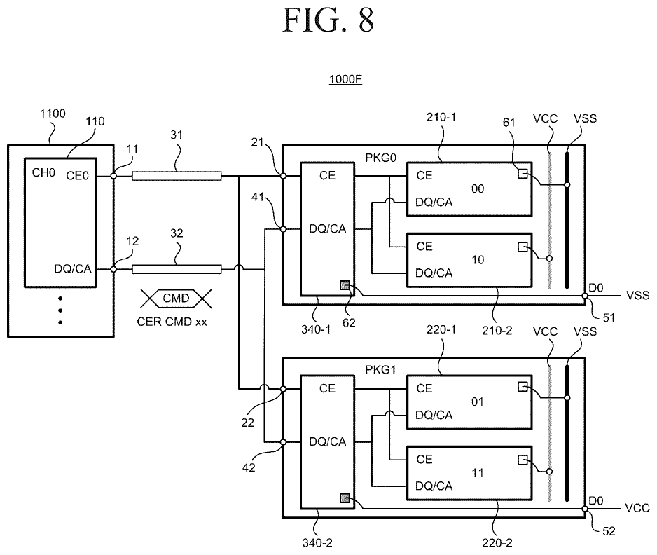

FIG. 8 is a block diagram of a storage device according to some example embodiments of the present disclosure. A storage device 1000F of FIG. 8 may be an implementation example embodiment of the storage device 1000 of FIG. 1, but example embodiments are not limited thereto.

Referring to FIG. 8, the storage device 1000F is the same as the storage device 1000E of FIG. 7 except for the package identification pads 62 are respectively placed in buffers 340-1 and 340-2, not the dies 210-1, 210-2, 220-1, and 220-2. Accordingly, additional description will be omitted to avoid redundancy, and a difference will be mainly described.

According to some example embodiments, the first package PKG0 may include the first buffer 340-1. The first buffer 340-1 may include the package identification pad 62 connected to the identification pin 51 of the first package PKG0. Meanwhile, the second package PKG1 may include the second buffer 340-2. The second buffer 340-2 may include the package identification pad 62 connected to the identification pin 52 of the second package PKG1.

In this case, whether each of the first and second buffers 340-1 and 340-2 operates may be determined based on a received CER command signal and a package identification voltage applied to the corresponding package identification pad 62.

In detail, the CER command signal CER CMD include a package identification bit. Also, a package identification voltage corresponding to a bit value of a package identification bit allocated to a corresponding package is applied to each of the identification pins 51 and 52 of the packages PKG0 and PKG1. Accordingly, each of the first and second buffers 340-1 and 340-2 may compare a bit value of a package identification bit corresponding to a package identification voltage applied to the package identification pad 62 included in the corresponding buffer and a bit value of a package identification bit included in the CER command signal CER CMD. When a comparison result indicates that the bit values are matched, the corresponding buffer operates; when a comparison result indicates that the bit values are not matched, the corresponding buffer does not operate.

For example, when the bit value of the package identification bit included in the CER command signal CER CMD is “0”, because the bit value is matched with the bit value (e.g., “0”) corresponding to the package identification voltage VSS applied to the package identification pad 62 of the first buffer 340-1, the first buffer 340-1 may operate. Accordingly, the CE signal CE0 and the CER command signal CER CMD may be transferred to the first dies 210-1 and 210-2. In this case, because the second buffer 340-2 does not operate, the CE signal CE0 and the CER command signal CER CMD are not transferred to the second dies 220-1 and 220-2.

Meanwhile, the CER command signal CER CMD may include a die identification bit; because each of the first dies 210-1 and 210-2 includes the die identification pad 61 to which a die identification voltage corresponding to the allocated die identification bit is applied, one of the first dies 210-1 and 210-2 may be selected. In this case, the selected die may include the die identification pad 61 to which the die identification voltage corresponding to the bit value of the die identification bit included in the CER command signal CER CMD is applied.

When the bit value of the die identification bit included in the CER command signal CER CMD is “1”, the second buffer 340-2 may operate, and thus, the CE signal CE0 and the CER command signal CER CMD may be transferred to the second dies 220-1 and 220-2. Accordingly, one of the second dies 220-1 and 220-2 may be selected.

The embodiments in which the controller 1100 of the storage device 1000, 1000A, 1000B, 1000C, 1000D, 1000E, or 1000F controls two packages PKG0 and PKG1 through one channel CH0 are described above, but example embodiments are not limited thereto. According to some example embodiments, the controller 1100 may control packages, the number of which is four, eight, or more, through one channel CH0. Even in this case, of course, one CE signal CE0 may be used.

According to some example embodiments, the controller 1100 may control four packages by using the CE signal CE0 of the channel CH0.

In this case, the storage device 1000 may include the first package PKG0 including first dies, the second package PKG1 including second dies, a third package PCK2 including third dies, and a fourth package PKG3 including fourth dies. In this case, each of the first to fourth packages PKG0 to PKG3 may have the same configuration as the first package PKG0 or the second package PKG1 illustrated in FIG. 2, 5, 6, 7, or 8.

Also, the storage device 1000 may include the first CE signal line 31 to which the CE signal CE0 is applied and the first command signal line 32 to which the CER command signal CER CMD is applied. In this case, each of the first CE signal line 31 and the first command signal line 32 may be connected in common to the first to fourth packages PKG0 to PKG3.

To control the four packages PKG0 to PKG3 to which the CE signal CE0 is applied in common, two package identification bits for distinguishing the fourth packages PKG0 to PKG3 may be required. Accordingly, an address allocated to each of the packages PKG0 to PKG3 may include two package identification bits (or 2-bit package identification information), and the controller 1100 may select one of the four packages PKG0 to PKG3 through the CER command signal CER CMD including the two package identification bits.

To this end, each of the packages PKG0 to PKG3 may include two identification pins (e.g., D1 and D0). Package identification voltages corresponding to two package identification bits allocated to the corresponding package may be respectively applied to the two identification pins D1 and D0. The package identification voltages applied to the identification pins D1 and D0 may be applied to package identification pads of dies included in the corresponding package (or according to some example embodiments, package identification pads of a buffer). In this case, each die or buffer may include two package identification pads.

Meanwhile, the CER command signal CER CMD may include a die identification bit as well as the package identification bit, and a die identification voltage corresponding to the allocated die identification bit may be applied to each of the first to fourth dies included in the packages PKG0 to PKG3. Accordingly, of course, it may be understood that one of the first to fourth dies included in the packages PKG0 to PKG3 is capable of being selected based on the CE signal CE0 and the CER command signal CER CMD.

Meanwhile, according to some example embodiments, the controller 1100 may control eight packages by using the CE signal CE0 of the channel CH0.

In this case, the storage device 1000 may include the first package PKG0 including first dies, the second package PKG1 including second dies, the third package PCK2 including third dies, the fourth package PKG3 including fourth dies, a fifth package PKG4 including fifth dies, a sixth package PKG5 including sixth dies, a seventh package PCK6 including seventh dies, and an eighth package PKG7 including eighth dies. In this case, each of the first to eighth packages PKG0 to PKG7 may have the same configuration as the first package PKG0 or the second package PKG7 illustrated in FIG. 2, 5, 6, 7, or 8.

Also, the storage device 1000 may include the first CE signal line 31 to which the CE signal CE0 is applied and the first command signal line 32 to which the CER command signal CER CMD is applied. In this case, each of the first CE signal line 31 and the first command signal line 32 may be connected in common to the first to eighth packages PKG0 to PKG7.

To control the eight packages PKG0 to PKG7 to which the CE signal CE0 is applied in common, three package identification bits for distinguishing the eight packages PKG0 to PKG7 may be required. Accordingly, an address allocated to each of the packages PKG0 to PKG7 may include three package identification bits (or 3-bit package identification information), and the controller 1100 may select one of the eight packages PKG0 to PKG7 through the CER command signal CER CMD including the three package identification bits.

To this end, each of the packages PKG0 to PKG7 may include three identification pins (e.g., D2, D1, and DO). Package identification voltages corresponding to three package identification bits allocated to the corresponding package may be respectively applied to the three identification pins D2, D1, and DO. The package identification voltages applied to the identification pins D2, D1, and D0 may be applied to package identification pads of dies included in the corresponding package (or according to some example embodiments, package identification pads of a buffer). To this end, each die or buffer may include three package identification pads.

Meanwhile, the CER command signal CER CMD may include a die identification bit as well as the package identification bit, and a die identification voltage corresponding to the allocated die identification bit may be applied to each of the first to eighth dies included in the packages PKG0 to PKG7. Accordingly, of course, it may be understood that one of the first to eighth dies included in the packages PKG0 to PKG7 is capable of being selected based on the CE signal CE0 and the CER command signal CER CMD.

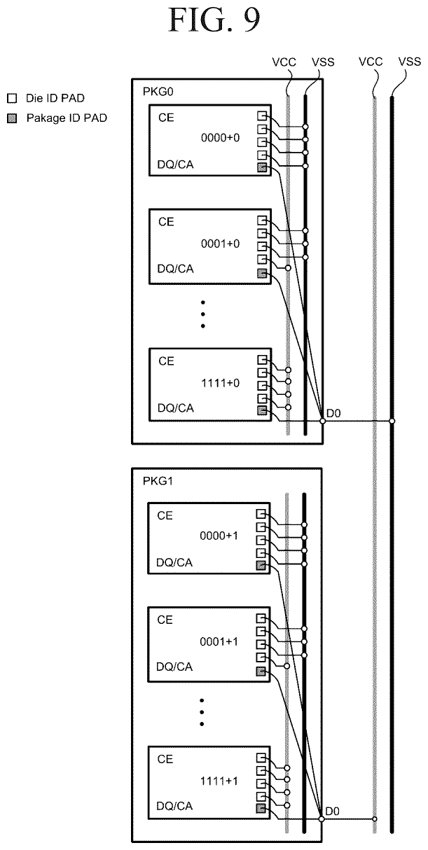

Below, various embodiments of the present disclosure associated with allocating addresses to dies will be described with reference to FIGS. 9 to 11.

FIG. 9 is a diagram illustrating an example of controlling two HDPs through one CE signal.

Referring to FIG. 9, the first package PKG0 and the second package PKG1 may be connected in common to one CE signal line. One package identification bit (or 1-bit package identification information) may be required to distinguish the first package PKG0 and the second package PKG1 connected in common to one CE signal line.

For example, the first package PKG0 and the second package PKG1 may be distinguished from each other by allocating a package identification bit value of “0” to the first package PKG0 and allocating a package identification bit value of “1” to the second package PKG1. To this end, each of the first package PKG0 and the second package PKG1 may include one identification pin DO. In this case, the identification pin D0 of the first package PKG0 may be connected to the ground voltage VSS, and the identification pin D0 of the second package PKG1 may be connected to the power supply voltage VCC. That is, a package identification voltage corresponding to the bit value of “0” may be applied to the first package PKG0, and a package identification voltage corresponding to the bit value of “1” may be applied to the second package PKG1. That is, a bit value of a package identification bit may be allocated to each package.

In this case, the ground voltage VSS may be applied to the identification pin D0 of the first package PKG0 from a ground plane included in a circuit board on which the packages PKG0 and PKG1 are mounted, and the power supply voltage VCC may be applied to the identification pin D0 of the second package PKG1 from a power plane included in the circuit board. However, example embodiments are not limited thereto. For example, according to some example embodiments, a separate circuit component for providing a voltage (e.g., a high level voltage or a low level voltage) corresponding to a package identification bit to the identification pin D0 may be provided.

The package identification voltage applied to the identification pin D0 may be applied to a package identification pad of each of dies included in the corresponding package. According to some example embodiments, the package identification voltage applied to the identification pin D0 may be applied to the package identification pad of the buffer 320-1, 320-2, 340-1, or 340-2 included in the corresponding package.

Meanwhile, each of the packages PKG0 and PKG1 may be an HDP. Because the HDP includes 16 dies, four die identification bits (or 4-bit die identification information) may be required to distinguish dies in a package.

According to some example embodiments, the 4-bit die identification information may have one of 16 values from “0000” to “1111”. Accordingly, the die identification bit values from “0000” to “1111” may be respectively allocated to the 16 dies in the package. To this end, each die may include four die identification pads. In this case, four die identification voltages respectively corresponding to four bit values allocated to the corresponding die may be respectively applied to the four die identification pads.

For example, four bits of the die identification information may include a first bit, a second bit, a third bit, and a fourth bit having different digits. Also, the four die identification pads may include a first pad corresponding to the first bit, a second pad corresponding to the second bit, a third pad corresponding to the third bit, and a fourth pad corresponding to the fourth bit.

In this case, “0000” may be allocated to the first die of the first package PKG0. In this case, all the four die identification pads included in the first die may be connected to the ground voltage VSS. Meanwhile, “0001” may be allocated to the second die of the first package PKG0. In this case, the first pad, the second pad, and the third pad among the four die identification pads included in the second die may be connected to the ground voltage VSS, and the fourth pad thereof may be connected to the power supply voltage VCC. Meanwhile, “0010” may be allocated to the third die of the first package PKG0. In this case, the first pad, the second pad, and the fourth pad among the four die identification pads included in the third die may be connected to the ground voltage VSS, and the third pad thereof may be connected to the power supply voltage VCC. Meanwhile, “1111” may be allocated to the 16th die of the first package PKG0. In this case, all the four die identification pads included in the 16th die may be connected to the power supply voltage VCC. As in the above description, die identification voltages may be applied to die identification pads of the remaining dies included in the first package PKG0.

That is, bit values of the die identification bits may be allocated to each die. The above description is also applied to the second package PKG1.

In this case, the ground voltage VSS may be applied to die identification pads of dies belonging to the corresponding package from the ground plane in the corresponding package, and the power supply voltage VCC may be applied to the die identification pads of the dies belonging to the corresponding package from the power plane in the corresponding package. However, example embodiments are not limited thereto. For example, according to some example embodiments, a separate circuit component for providing a voltage (e.g., a high level voltage or a low level voltage) corresponding to a die identification bit may be provided in a package.

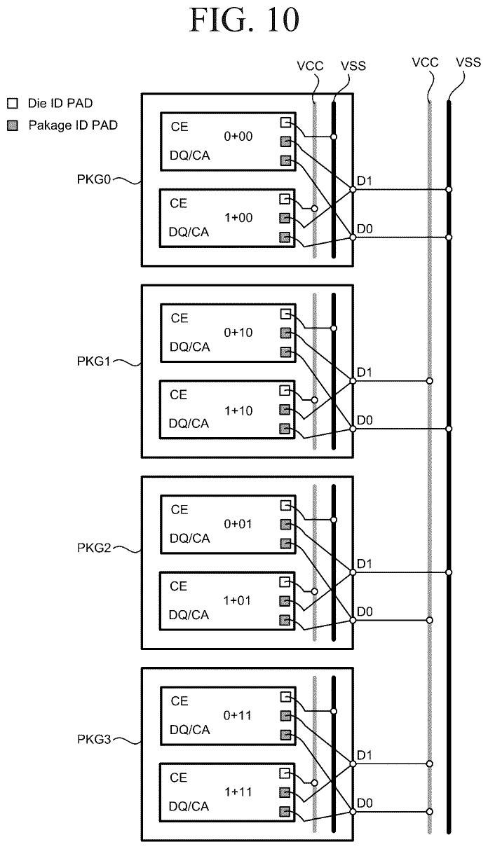

FIG. 10 is a diagram illustrating an example of four DDPs through one CE signal.

Referring to FIG. 10, the first package PKG0, the second package PKG1, the third package PCK2, and the fourth package PKG3 may be connected in common to one CE signal line. Two package identification bits (or 2-bit package identification information) may be required to distinguish the first package PKG0, the second package PKG1, the third package PCK2, and the fourth package PKG3 connected in common to one CE signal line.

For example, the first package PKG0, the second package PKG1, the third package PCK2, and the fourth package PKG3 may be distinguished from each other by allocating a package identification bit value of “00” to the first package PKG0, allocating a package identification bit value of “10” to the second package PKG1, allocating a package identification bit value of “01” to the third package PCK2, and allocating a package identification bit value of “11” to the fourth package PKG3. To this end, each of the first package PKG0, the second package PKG1, the third package PCK2, and the fourth package PKG3 may include two identification pins D1 and D0. In this case, both the identification pin D1 and the identification pin D0 of the first package PKG0 may be connected to the ground voltage VSS. Also, the identification pin D1 of the second package PKG1 may be connected to the power supply voltage VCC, and the identification pin D0 of the second package PKG1 may be connected to the ground voltage VSS. In addition, the identification pin D1 of the third package PCK2 may be connected to the ground voltage VSS, and the identification pin D0 of the third package PCK2 may be connected to the power supply voltage VCC. Furthermore, both the identification pin D1 and the identification pin D0 of the fourth package PKG3 may be connected to the power supply voltage VCC. That is, package identification voltages corresponding to the allocated bit value of “00” may be applied to the first package PKG0, package identification voltages corresponding to the allocated bit value of “10” may be applied to the second package PKG1, package identification voltages corresponding to the allocated bit value of “01” may be applied to the third package PCK2, and package identification voltages corresponding to the allocated bit value of “11” may be applied to the fourth package PKG3. That is, a bit value of package identification bits may be allocated to each package.

In this case, the ground voltage VSS may be provided from a ground plane implemented outside the package, and the power supply voltage VCC may be provided from a power plane implemented outside the package. However, example embodiments are not limited thereto. According to some example embodiments, package identification voltages applied to the identification pins D1 and D0 may be provided from a separate circuit component providing the high level voltage or the low level voltage.

The package identification voltage applied to the identification pins D1, D0 may be applied to package identification pads of each of dies included in the corresponding package. To this end, each die may include two package identification pads. One of the two package identification pads may be connected to the identification pin D1, and the other thereof may be connected to the identification pin DO. Meanwhile, according to some example embodiments, the package identification voltage applied to the identification pins D1 and D0 may be respectively applied to the package identification pads of the buffer 320-1, 320-2, 340-1, or 340-2 included in the corresponding package. To this end, the buffer 320-1, 320-2, 340-1, or 340-2 may include two package identification pads.

Meanwhile, each of the first and fourth packages PKG0 to PKG3 may be a DDP. Because the DDP includes two dies, two dies in the package may be distinguished from each other by using one die identification bit (or 1-bit die identification information). According to some example embodiments, a bit value of “0” may be allocated to one of two dies included in each of the first and fourth packages PKG0 to PKG3, and a bit value of “1” may be allocated to the other thereof. In this case, a die identification voltage (e.g., VCC or VSS) corresponding to the bit value allocated to the die may be applied to a die identification pad of the die. That is, a bit value of the die identification bit may be allocated to each die. A source of a die identification voltage is described above, and thus, additional description will be omitted to avoid redundancy.

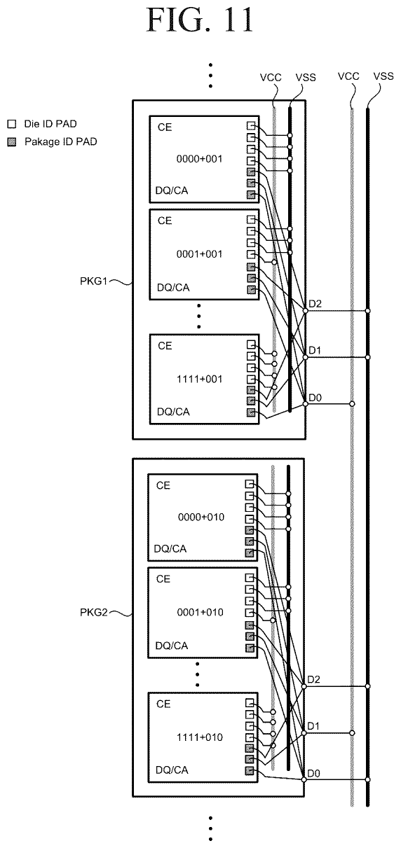

FIG. 11 is a diagram illustrating an example of controlling eight HDPs through one CE signal. Only two HDPs PKG1 and PKG2 among eight HDPs are illustrated in FIG. 11, but it is assumed that eight HDPs from PKG0 to PKG7 are included.

Referring to FIG. 11, the first package PKG0 to the eighth package PKG7 may be connected in common to one CE signal line. Three package identification bits (or 3-bit package identification information) may be required to distinguish the first package PKG0 to the eighth package PKG7 connected in common to one CE signal line.

According to some example embodiments, eight 3-bit package identification values from “000” to “111” may be respectively allocated to the first package PKG0 to the eighth package PKG7. Accordingly, the first package PKG0 to the eighth package PKG7 may be distinguished from each other. To this end, each of the first package PKG0 to the eighth package PKG7 may include three identification pins D2, D1, DO. Package identification voltages corresponding to bit values of a package identification bit allocated to the package may be respectively applied to the three identification pins D2, D1, and DO.

In this case, the three package identification bits may include a first bit, a second bit, and a third bit having different digits. Also, the identification pin D2 among the three identification pins D2, D1, and D0 may correspond to the first bit, the identification pin D1 thereof may correspond to the second bit, and the identification pin D0 may correspond to the third bit. In this case, to allocate a package identification bit value of “000” to the first package PKG0, all the identification pins D2, D1, and D0 may be connected to the ground voltage VSS. Also, to allocate a package identification bit value of “001” to the second package PKG1, the identification pins D2 and D1 may be connected to the ground voltage VSS, the identification pin D0 may be connected to the power supply voltage VCC. In addition, to allocate a package identification bit value of “010” to the third package PCK2, the identification pins D2 and DO may be connected to the ground voltage VSS, the identification pin D1 may be connected to the power supply voltage VCC. As in the above description, package identification bits may be allocated to the remaining packages. Sources of package identification voltages (e.g., VCC and VSS) are described above, and thus, additional description will be omitted to avoid redundancy.

The package identification voltages applied to the identification pins D2, D1, D0 may be applied to package identification pads of each of dies included in the corresponding package. To this end, each die may include three package identification pads. The three package identification pads may be connected to the three identification pins D2, D1, and D0 in a one-to-one correspondence. Meanwhile, according to some example embodiments, the package identification voltages applied to the identification pins D2, D1, and D0 may be applied to the package identification pads of the buffer 320-1, 320-2, 340-1, or 340-2 included in the corresponding package. To this end, the buffer 320-1, 320-2, 340-1, or 340-2 may include three package identification pads.

Meanwhile, each of the first to eighth packages PKG0 to PKG7 may be an HDP. Because the HDP includes 16 dies, four die identification bits (or 4-bit die identification information) may be required to distinguish dies in a package. The way to allocate 4-bit die identification information to each die to distinguish 16 dies in the HDP is described in detail with reference to FIG. 9, and thus, additional description will be omitted to avoid redundancy.

Meanwhile, to control a plurality of packages by using one CE signal (e.g., CE0) does not mean to necessarily control all the dies included in the plurality of packages by using one CE signal (e.g., CE0). That is, according to some example embodiments of the present disclosure, at least some of the dies included in each of the plurality of packages may be controlled by using one CE signal (e.g., CE0).

That is, the case where each package is a 1CE package including one CE signal pin (e.g., 21 or 22) is described above as an example, but some example embodiments is not limited thereto. For example, each of the above packages may include a 2CE package including two CE signal pins or may be a 4CE package including four CE signal pins. In this case, one CE signal may be applied to some of dies included in the plurality of packages to which the corresponding CE signal is applied.

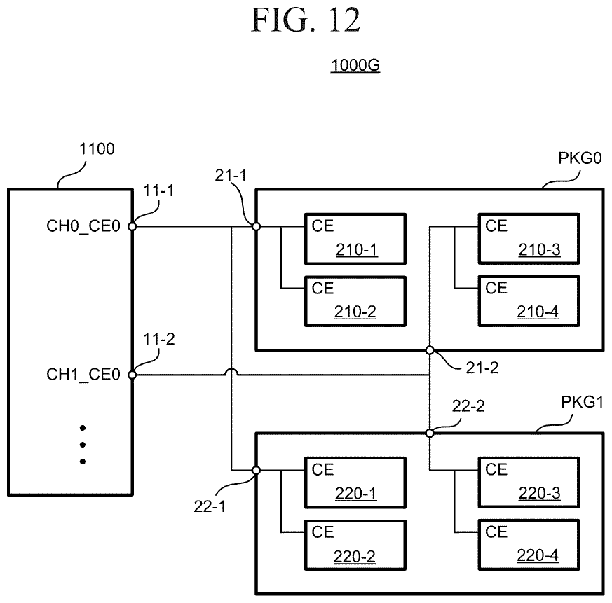

FIG. 12 is a block diagram of a storage device according to some example embodiments of the present disclosure. A storage device 1000G of FIG. 12 may be an implementation example embodiment of the storage device 1000 of FIG. 1, but example embodiments are not limited thereto. In describing FIG. 12, the description which is given above will be omitted.

Referring to FIG. 12, the storage device 1000G may include the controller 1100, the first package PKG0, and the second package PKG1.

The first package PKG0 may include a first CE pin 21-1, a second CE pin 21-2, and first dies 210-1, 210-2, 210-3, and 210-4. In this case, the CE pads CE of some 210-1 and 210-2 of the first dies 210-1, 210-2, 210-3, and 210-4 may be connected to the first CE pin 21-1, and the CE pads CE of the others 210-3 and 210-4 thereof may be connected to the second CE pin 21-2.

The second package PKG1 may include a first CE pin 22-1, a second CE pin 22-2, and second dies 220-1, 220-2, 220-3, and 220-4. In this case, the CE pads CE of some 220-1 and 220-2 of the second dies 220-1, 220-2, 220-3, and 220-4 may be connected to the first CE pin 22-1, and the CE pads CE of the others 220-3 and 220-4 thereof may be connected to the second CE pin 22-2.

Because each of the first and second packages PKG0 and PKG1 includes two CE pins, each of the first and second packages PKG0 and PKG1 may be a 2CE package.

The controller 1100 may include a first CE pin 11-1 of outputting a first CE signal CH0_CE0 and a second CE pin 11-2 of outputting a second CE signal CH1_CE0. In this case, the first CE signal CH0_CE0 may correspond to the first channel CH0, and the second CE signal CH1_CE0 may correspond to the second channel CH1.

Meanwhile, although not illustrated in drawings, the storage device 1000G may include a first CE signal line which include a first end connected to the first CE pin 11-1 of the controller 1100 and a second end connected in common to the first CE pin first 21-1 of the first package PKG0 and the first CE pin 22-1 of the second package PKG1. Also, the storage device 1000G may include a second CE signal line which includes a first end connected to the second CE pin 11-2 of the controller 1100 and a second end connected in common to the second CE pin 21-2 of the first package PKG0 and the second CE pin 22-2 of the second package PKG1.

For convenience of illustration, a command pin and a command signal line may not be illustrated, but the command pin and the command signal line may be provided for each channel as described with reference to FIG. 8.

In this case, the controller 1100 may select one of the dies 210-1, 210-2, 220-1, and 220-2 connected in common to the first CE signal line through the first channel CH0. In detail, the controller 1100 may select one of the dies 210-1, 210-2, 220-1, and 220-2 connected in common to the first CE signal line by applying the first CE signal CH0_CE0 to the first CE signal line and applying the CER command signal to the command signal line corresponding to the first channel CH0.

Also, the controller 1100 may select one of the dies 210-3, 210-4, 220-3, and 220-4 connected in common to the second CE signal line through the second channel CH1. In detail, the controller 1100 may select one of the dies 210-3, 210-4, 220-3, and 220-4 connected in common to the second CE signal line by applying the second CE signal CH1_CE0 to the second CE signal line and applying the CER command signal to the command signal line corresponding to the second channel CH1.

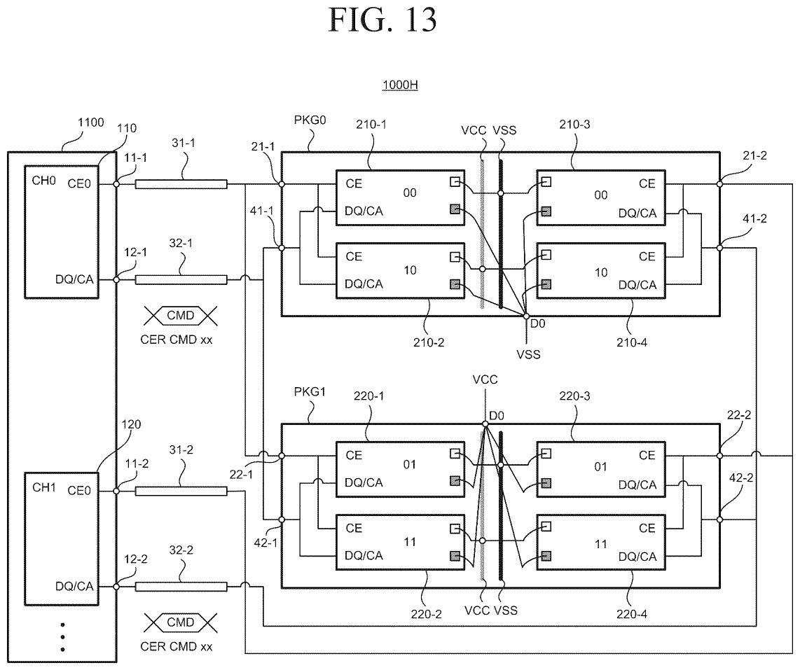

FIG. 13 is a block diagram of a storage device according to some example embodiments of the present disclosure. A storage device 1000H of FIG. 13 may be an implementation example embodiment of the storage device 1000 of FIG. 1 or the storage device 1000G of FIG. 12, but example embodiments are not limited thereto. In describing FIG. 13, the description which is given above will be omitted.

Referring to FIG. 13, the storage device 1000H may include the controller 1100, the first package PKG0, the second package PKG1, a first CE signal line 31-1, a first command signal line 32-1, a second CE signal line 31-2, and a second command signal line 32-2.

The first package PKG0 may include the first dies 210-1, 210-2, 210-3, and 210-4. In this case, each of the first dies 210-1, 210-2, 210-3, and 210-4 may receive the CE signal through the CE pad CE and may receive the command signal through the command pad DQ/CA.

The first package PKG0 may include the first CE pin 210-1 and the second CE pin 210-2. The first CE pin 21-1 may be connected in common to the CE pads CE of some 210-1 and 210-2 of the first dies 210-1, 210-2, 210-3, and 210-4. The second CE pin 21-1 may be connected in common to the CE pads CE of the others 210-3 and 210-4 of the first dies 210-1, 210-2, 210-3, and 210-4.

Meanwhile, the first package PKG0 may include a first command pin 41-1 and a second command pin 41-2. The first command pin 41-1 may be connected in common to the command pads DQ/CE of some 210-1 and 210-2 of the first dies 210-1, 210-2, 210-3, and 210-4. The second command pin 41-2 may be connected in common to the command pads DQ/CE of the others 210-3 and 210-4 of the first dies 210-1, 210-2, 210-3, and 210-4.

Because the first package PKG0 includes four dies 210-1, 210-2, 210-3, and 210-4 and includes two CE pins 21-1 and 21-2, the first package PKG0 may be the 2CE QDP.

The second package PKG1 may be similar in configuration to the first package PKG0. In detail, the second package PKG1 may include the second dies 220-1, 220-2, 220-3, and 220-4. Each of the second dies 220-1, 220-2, 220-3, and 220-4 may receive the CE signal through the CE pad CE and may receive the command signal through the command pad DQ/CA.

The second package PKG1 may include the first CE pin 22-1 and the second CE pin 22-2. The first CE pin 22-1 may be connected in common to the CE pads CE of some 220-1 and 220-2 of the second dies 220-1, 220-2, 220-3, and 220-4. The second CE pin 22-2 may be connected in common to the CE pads CE of the others 220-3 and 220-4 of the second dies 220-1, 220-2, 220-3, and 220-4.

The second package PKG1 may include a first command pin 42-2 and a second command pin 42-2. The first command pin 42-1 may be connected in common to the command pads DQ/CE of some 220-1 and 220-2 of the second dies 220-1, 220-2, 220-3, and 220-4. The second command pin 42-2 may be connected in common to the command pads DQ/CE of the others 220-3 and 220-4 of the second dies 220-1, 220-2, 220-3, and 220-4.

Because the second package PKG1 also includes four dies 220-1, 220-2, 220-3, and 220-4 and includes two CE pins 22-1 and 22-2, the second package PKG1 may be the 2CE QDP.

Meanwhile, an address may be allocated to each of the dies 210-1, 210-2, 210-3, 210-4, 220-1, 220-2, 220-3, and 220-4 included in the first and second packages PKG0 and PKG1. In some example embodiments, the address may include a package identification bit for distinguishing packages and a die identification bit for distinguishing dies. Meanwhile, according to some example embodiments, the address may be allocated for each channel. The controller 1100 of the storage device 1000H may control the first and second packages PKG0 and PKG1 by using two channels CH0 and CH1. Accordingly, addresses may be allocated to dies 210-1, 210-2, 220-1, and 220-2 controlled through the first channel CH0 from among the dies 210-1, 210-2, 210-3, 210-4, 220-1, 220-2, 220-3, and 220-4 included in the first and second packages PKG0 and PKG1 by using the method described above. Also, addresses may be allocated to dies 210-3, 210-4, 220-3, and 220-4 controlled through the second channel CH1 from among the dies 210-1, 210-2, 210-3, 210-4, 220-1, 220-2, 220-3, and 220-4 included in the first and second packages PKG0 and PKG1 by using the method described above. The way to allocate addresses is described above, and thus, additional description will be omitted to avoid redundancy.

The controller 1100 may include the first control circuit 110 which generates the first CE signal CE0 corresponding to the first channel CH0 and the first command signal DQ/CA. The first CE signal CE0 and the first command signal DQ/CA generated by the first control circuit 110 may be respectively output to the first CE pin 11-1 and a first command pin 12-1 of the controller 1100.

Also, the controller 1100 may include a second control circuit 120 which generates the second CE signal CE0 corresponding to the second channel CH1 and the second command signal DQ/CA. The second CE signal CE0 and the second command signal DQ/CA generated by the second control circuit 120 may be respectively output to the second CE pin 11-2 and a second command pin 12-2 of the controller 1100.

A first end of a first CE signal line 31-1 may be connected to the first CE pin 11-1 of the controller 1100, and a second end of the first CE signal line 31-1 may be connected to the first CE pin 21-1 of the first package PKG0 and the second CE pin 22-1 of the second package PKG1.

A first end of a first command signal line 32-1 may be connected to the first command pin 12-1 of the controller 1100, and a second end of the first command signal line 32-1 may be connected to the first command pin 41-1 of the first package PKG0 and the first command pin 42-1 of the second package PKG1. In this case, the first command signal line 32-1 may be implemented with a command/address signal line; according to some example embodiments, the first command signal line 32-1 may be implemented with a data signal line.

A first end of a second CE signal line 31-2 may be connected to the second CE pin 11-2 of the controller 1100, and a second end of the second CE signal line 31-2 may be connected to the second CE pin 21-2 of the first package PKG0 and the second CE pin 22-2 of the second package PKG1.

A first end of a second command signal line 32-2 may be connected to the second command pin 12-2 of the controller 1100, and a second end of the second command signal line 32-2 may be connected to the second command pin 41-2 of the first package PKG0 and the second command pin 42-2 of the second package PKG1. In this case, the second command signal line 32-2 may be implemented with a command/address signal line; according to some example embodiments, the second command signal line 32-2 may be implemented with a data signal line.

The first and second CE signal lines 31-1 and 31-2 and the first and second command signal lines 32-1 and 32-2 may be formed in the circuit board of the storage device 1000H, on which the controller 1100, the first package PKG0, and the second package PKG1 are mounted.

Meanwhile, the controller 1100 may select one of the dies 210-1, 210-2, 220-1, and 220-2 connected in common to the first CE signal line 31-1 by applying the first CE signal CE0 corresponding to the first channel CH0 to the first CE signal line 31-1 and applying the first CER command signal CER CMD corresponding to the first channel CH0 to the first command signal line 32-1. In some example embodiments, the CER command signal CER CMD may include a die identification bit and a package identification bit allocated to a die to be selected.

In this case, the first CE signal CE0 of the low level may be applied to all the dies 210-1, 210-2, 220-1, and 220-2 connected in common to the first CE signal line 31-1, but one die corresponding to the die identification bit and the package identification bit included in the CER command signal CER CMD may be selected.

Also, the controller 1100 may select one of the dies 210-3, 210-4, 220-3, and 220-4 connected in common to the second CE signal line 31-2 by applying the second CE signal CE0 corresponding to the second channel CH1 to the second CE signal line 31-2 and applying the second CER command signal CER CMD corresponding to the second channel CH1 to the second command signal line 32-2. In some example embodiments, the CER command signal CER CMD may include a die identification bit and a package identification bit allocated to a die to be selected. In this case, the second CE signal CE0 of the low level may be applied to all the dies 210-3, 210-4, 220-3, and 220-4 connected in common to the second CE signal line 31-2, but one die corresponding to the die identification bit and the package identification bit included in the CER command signal CER CMD may be selected.

In FIG. 12, the case where each of the first and second packages PKG0 and PKG1 is the QDP including four dies is provided as an example, but example embodiments are not limited thereto. According to some example embodiments, each of the first and second packages PKG0 and PKG1 may be the DDP, the ODP, the HDP, or the 32DP or may be a multi-chip package including dies, the number of which is different from those of the examples.

According to various example embodiments of the present disclosure described above, there may be provided a storage device in which the number of CE pins of a controller and the number of CE signal lines are decreased. This may mean that the size of a storage device and/or manufacturing costs are reduced.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. A storage device comprising:
a first package including first dies;
a second package including second dies;
a first chip enable (CE) signal line connected in common to the first and second packages;
a first command signal line connected in common to the first and second packages; and
a controller configured to
select one die of dies included in packages connected in common to the first CE signal line by applying a CE signal to the first CE signal line and a chip enable reduction (CER) command signal to the first command signal line,
wherein the CER command signal includes
at least one package identification bit for package selection and
at least one die identification bit for die selection, and
each of the first and second packages includes at least one identification pin,
the at least one identification pin applied with at least one package identification voltage respectively corresponding to the at least one package identification bit.

2. The storage device of claim 1, wherein
the first package includes a first CE pin connected in common to CE pads of the first dies,
the second package includes a second CE pin connected in common to CE pads of the second dies, and
the first CE signal line is connected in common to the first CE pin and the second CE pin.

3. The storage device of claim 1, wherein
the first package includes a first command pin connected in common to command pads of the first dies,
the second package includes a second command pin connected in common to command pads of the second dies, and
the first command signal line is connected in common to the first command pin and the second command pin.

4. The storage device of claim 1, wherein
the at least one package identification voltage includes two different voltage levels applied from outside of the first and second packages, and
each of the at least one identification pin is configured to have one voltage level of the two different voltage levels.

5. The storage device of claim 4, wherein
the at least one package identification bit includes a bit value differently set for each package, and
each of the at least one package identification voltage includes a voltage level corresponding to a bit value of each of the at least one package identification bit corresponding to a relevant package.

6. The storage device of claim 1, wherein
each of the first dies and the second dies includes at least one die identification pad applied with at least one die identification voltage respectively corresponding to the at least one die identification bit.

7. The storage device of claim 6, wherein
each of the first dies and the second dies includes at least one package identification pad respectively connected to the at least one identification pin.

8. The storage device of claim 7, wherein
the selected one die includes
a package identification pad applied with a package identification voltage corresponding to a bit value of a package identification bit included in the CER command signal, and
a die identification pad applied with a die identification voltage corresponding to a bit value of a die identification bit included in the CER command signal.

9. The storage device of claim 1, wherein
the first package includes a first buffer configured to receive the CER command signal and to transfer the received CER command signal to the first dies in response to the CE signal, and
the second package includes a second buffer configured to receive the CER command signal and to transfer the received CER command signal to the second dies in response to the CE signal.

10. The storage device of claim 9, wherein
each of the first buffer and the second buffer includes at least one package identification pad respectively connected to the at least one identification pin, and
each of the first buffer and the second buffer is determined to operate based on the received CER command signal and a package identification voltage applied to the package identification pad.

11. The storage device of claim 1, wherein
the first package includes a third buffer configured to
receive the CE signal and the CER command signal, and
to transfer the received CE signal and the received CER command signal to the first dies, and
the second package includes a fourth buffer configured to
receive the CE signal and the CER command signal, and
to transfer the received CE signal and the received CER command signal to the second dies.

12. The storage device of claim 11, wherein
each of the third buffer and the fourth buffer includes at least one package identification pad respectively connected to the at least one identification pin, and
each of the third buffer and the fourth buffer is determined to operate based on the received CER command signal and a package identification voltage applied to the package identification pad.

13. The storage device of claim 1, wherein
the CER command signal includes one package identification bit,
each of the first and second packages includes one identification pin to which one identification voltage corresponding to the one package identification bit is applied, and
the controller selects one die of the first dies and the second dies based on the CE signal and the CER command signal.

14. The storage device of claim 1, further comprising:
a third package including third dies; and
a fourth package including fourth dies,
wherein each of the first CE signal line and the first command signal line is connected in common to the first to fourth packages,
the CER command signal includes two package identification bits,
each of the first to fourth packages includes two identification pins applied with two package identification voltages respectively corresponding to the two package identification bits, and
the controller is configured to select one die of the first dies to fourth dies based on the CE signal and the CER command signal.

15. The storage device of claim 1, further comprising:
a third package including third dies;
a fourth package including fourth dies;
a fifth package including fifth dies;
a sixth package including sixth dies;
a seventh package including seventh dies; and
an eighth package including eighth dies,
wherein each of the first CE signal line and the first command signal line is connected in common to the first to eighth packages,
wherein the CER command signal includes three package identification bits,
each of the first to eighth packages includes three identification pins applied with three package identification voltages respectively corresponding to the three package identification bits, and
the controller is configured to select one die of the first dies to eighth dies based on the CE signal and the CER command signal.

16. The storage device of claim 1, wherein
the first dies are among a plurality of first package dies included in the first package, and
the second dies are among a plurality of second package dies included in the second package.

17. The storage device of claim 16, further comprising:
a second CE signal line connected in common to the first and second packages; and
a second command signal line connected in common to the first and second packages,
wherein the first package further includes third dies,
the second package further includes fourth dies,
the controller is configured to select one die of the third dies and fourth dies by applying the CE signal to the second CE signal line and applying the CER command signal to the second command signal line,
the first CE signal line and the first command signal line correspond to a first channel, and
the second CE signal line and the second command signal line correspond to a second channel.

18. The storage device of claim 1, wherein
the first package and the second package are one of a dual die package (DDP), a quadruple die package (QDP), an octuple die package (ODP), a hexadecimal die package (HDP), or a 32 die package (32DP).

19. A storage device comprising:
a plurality of NAND packages;
a controller configured to control the plurality of NAND packages through a plurality of channels; and
a plurality of chip enable (CE) signal lines configured to transfer a plurality of CE signals respectively corresponding to the plurality of channels of the plurality of NAND packages,
wherein the plurality of NAND packages include
a first NAND package including a plurality of first dies and a first CE pin connected in common to at least one of the plurality of first dies, and
a second NAND package including a plurality of second dies and a second CE pin connected in common to at least one of the plurality of second dies,
the controller includes a third CE pin configured to output a first CE signal corresponding to a first channel among the plurality of channels,
the plurality of CE signal lines include a first CE signal line including
a first end connected to the third CE pin, and
a second end connected in common to the first CE pin and the second CE pin, and
each of the first and second NAND packages includes an identification pin applied with a package identification voltage for distinguishing the first NAND package and the second NAND package.

20. A storage device comprising:
a first package including
a first chip enable (CE) pin,
first dies connected in common to the first CE pin,
a second CE pin, and
second dies connected in common to the second CE pin;
a second package including
a third CE pin,
third dies connected in common to the third CE pin,
a fourth CE pin, and
fourth dies connected in common to the fourth CE pin;
a controller including
a fifth CE pin configured to output a first CE signal corresponding to a first channel, and
a sixth CE pin configured to output a second CE signal corresponding to a second channel;
a first CE signal line including
a first end connected to the fifth CE pin, and
a second end connected in common to the first CE pin and the third CE pin; and
a second CE signal line including
a first end connected to the sixth CE pin, and
a second end connected in common to the second CE pin and the fourth CE pin,
wherein each of the first and second packages includes an identification pin applied with an identification voltage for distinguishing the first and second packages.
